(19) United States
(12) Patent Application Publication
(10) Pub. No.: US 2015/0263285 A1
(43) Pub. Date: Sep. 17, 2015

(54) POLYMER SOLAR CELL AND PREPARATION METHOD THEREOF

(71) Applicants: Mingjie ZHOU, (US); Ping WANG, (US); Hui HUANG, (US); Jixing CHEN, (US)

(72) Inventors: Mingjie Zhou, Shenzhen (CN); Ping Wang, Shenzhen (CN); Hui Huang, Shenzhen (CN); Jixing Chen, Shenzhen (CN)

(73) Assignee: OCEAN'S KING LIGHTING SCIENCE & TECHNOLOGY CO., LTD., Nanshan District, Shenzdhen, Guangdong (CN)

(21) Appl. No.: 14/431,993

(22) PCT Filed: Sep. 28, 2012
(86) PCT No.: PCT/CN2012/082257

§ 371 Date: Mar. 27, 2015

(51) Int. Cl. H01L 51/00

(52) U.S. Cl. CPC H01L 51/0007; H01L 51/441

(57) ABSTRACT

Disclosed are a polymer solar cell and a preparation method thereof. The preparation method comprises: successively preparing on a clean glass substrate (1), a cathode (2), an electronic buffer layer (3) and an active layer (4) by the steps of dissolving poly(3,4-ethylenedioxythiophene) and polymerized p-styrene sulphonic acid, dissolving zinc oxide into acetic acid to obtain a zinc oxide solution, mixing the zinc oxide solution with the solution of poly(3,4-ethylenedioxythiophene) and polymerized p-styrene sulphonic acid to obtain a mixed solution, spin-coating the mixed solution on the active layer (4) and then by drying to obtain the anode (5), and finally obtain the polymer solar cell.

### FIELD OF THE INVENTION

The present invention relates to the field of solar cell technique, especially to a polymer solar cell and preparation method thereof.

### BACKGROUND OF THE INVENTION

In 1982, Weinberger et al. studied photovoltaic properties of polyacetylene and produced a first significant solar cell. However, it had an extremely low photoelectric conversion efficiency of 10⁻³%. Glenis et al. then produced various polythiophene solar cells, but a common problem was low open-circuit voltage and low photoelectric conversion efficiency. Until 1986, C. W. Tang et al. greatly increased photoelectric current by introducing p-type semiconductor and n-type semiconductor into a double layer solar cell for the first time. This is a landmark in the history of development of organic polymer solar cell.

A double layer polymer solar cell comprises a positive electrode, a negative electrole and a thin film having photic activity between them. The thin film is active layer. Normally, active layer has a heterogeneous structure consisting of donor (D) and acceptor (A). Main material of donor comprises CdSe, n-polymer, C₆₀ and its derivative PCBM. A solar cell of PCBM could adopt indium tin oxide (ITO) and metal having relatively low work function as positive electrode and negative electrode, respectively. Active layer is generally obtained by mixing conjugated polymer with PCBM. In the case that the light travels through a transparent ITO and reaches conjugated polymer molecules, an exciton can form when photon energy is larger than bandgap of polymer. The exciton moves towards the interface of donoracceptor (D/A). The difference between D/A is larger than the binding energy of the exciton, which will lead to the separation of excitons at the interface. PCBM transports electrons to the negative electrode, whereas polymer transports holes to the positive electrode ITO, thus generating photoelectric current and photovoltage.

To increase power conversion efficiency, absorption of sunlight has been normally improved by the modification of structure of material of active layer. But this method has some drawbacks, such as high cost and time-consuming. Furthermore, when the sunlight reaches the active layer, only a small amount of the light can be absorbed and utilized. Most of the sunlight passes through the cell without being utilized. Therefore, an important way to improve utilization of sunlight and increase power conversion efficiency is to improve component or structure of polymer solar cell. However, little related research has been done and reported.

### SUMMARY OF THE INVENTION

In order to solve the above problems, the present invention aims to provide a method for preparing polymer solar cell. Anode of the polymer solar cell of the present invention is prepared by mixing poly(3,4-ethylenedioxythiophene) (PEDOT) and polystyrene sulfonate (PSS) with zinc oxide (ZnO). Difference between anode and active layer in refractive index causes the sunlight passing through the active layer to be scattered and totally reflected, and then absorbed, thus improving utilization of the sunlight and increasing power conversion efficiency of polymer solar cell.

The present invention further provides a polymer solar cell prepared by the above method.

In a first aspect, the present invention provides a method for preparing polymer solar cell, comprising:
providing a clean glass substrate and then preparing a cathode, an electronic buffer layer and an active layer successively on the glass substrate;
preparing an anode on the active layer by the following steps:
   dissolving poly(3,4-ethylenedioxythiophene) (PEDOT) and polystyrene sulfonate (PSS) in chlorobenzene to obtain a solution of poly(3,4-ethylenedioxythiophene) and polystyrene sulfonate, where a weight of poly(3,4-ethylenedioxythiophene) and polystyrene sulfonate are in a ratio 2:1-6:1, and a percentage of poly(3,4-ethylenedioxythiophene) by weight of the solution of poly(3,4-ethylenedioxythiophene) and polystyrene sulfonate is in a range of 1%-5%;
   dissolving zinc oxide in acetic acid to obtain a zinc oxide solution with a concentration of 0.05 g/ml-0.6 g/ml;
   mixing the zinc oxide solution and the solution of poly(3,4-ethylenedioxythiophene) and polystyrene sulfonate in a volume ratio 1:10-3:4 to obtain a mixed solution, where a weight of zinc oxide and poly(3,4-ethylenedioxythiophene) are in a ratio 0.75:1-6:1;
   spin-coating the mixed solution on the active layer, and then drying to obtain the anode;
obtaining a polymer solar cell.

Preferably, a particle size of the zinc oxide is in a range of 50 nm-200 nm.

Zinc oxide is dissolved with acetic acid because acetic acid is a weak acid and is less corrosive to glass. Other concentrations of the acetic acid solutions are also permitted for the purpose of dissolving zinc oxide. After dissolving zinc oxide, water should be removed by drying. Concentration of the zinc oxide solution is ratio of the mass of zinc oxide to the volume of acetic acid. Both of density of the zinc oxide solution and density of the solution of poly(3,4-ethylenedioxythiophene) and polystyrene sulfonate are deemed to be 1 mg/ml.

Molecular weight of the PEDOT is in a normal range of 13000-50000.

Preferably, the step of spin-coating is conducted at a speed of 2000 rpm-6000 rpm for 10 s-60 s.

Preferably, the step of drying is conducted in an inert atmosphere at a temperature of 50° C.-200° C. for 10 minutes-30 minutes.

Preferably, a thickness of the anode is in a range of 100 nm-300 nm.

Preferably, the glass substrate is common and commercially available glass.

Preferably, a material of the cathode is aluminium (Al), silver (Ag), gold (Au) or platinum (Pt). More preferably, material of the cathode is aluminium (Al).

Preferably, the cathode is prepared by vacuum vapor deposition, and the vapor deposition is conducted at a pressure of 2×10⁻⁵ Pa-5×10⁻³ Pa at a speed of 1 nm/s-10 nm/s.

Preferably, a thickness of the cathode is in a range of 10 nm-30 nm. More preferably, the thickness of the cathode is 15 nm.

Preferably, a material of the electronic buffer layer is lithium fluoride (LiF), lithium carbonate (Li₂CO₃) or cesium carbonate (Cs₂CO₃). More preferably, the material of the electronic buffer layer is cesium carbonate (Cs₂CO₃).

Preferably, electronic buffer layer is prepared by vacuum vapor deposition, and the vapor deposition is conducted at a pressure of 2×10⁻⁵ Pa-5×10⁻³ Pa at a speed of 0.1 nm/s-1 nm/s.

More preferably, a thickness of the electronic buffer layer is in a range of 0.5 nm-10 nm. More preferably, the thickness of the electronic buffer layer is 2 nm.

Preferably, material of the active layer comprises poly(3-hexylthiophene) (P3HT) and [6,6]-phenyl-C₆₁-butyric acid methyl ester (PCBM). [6,6]-phenyl-C61-butyric acid methyl ester which is derived from C₆₀ has a molecular formula of C₇₂H₁₄O₂.

Preparation of an active layer comprises: dissolving poly(3-hexylthiophene) (P3HT) and [6,6]-phenyl-C61-butyric acid methyl ester (PCBM) in a solvent to obtain a mixed solution of poly(3-hexylthiophene) (P3HT) and [6,6]-phenyl-C61-butyric acid methyl ester (PCBM), where a weight of poly(3-hexylthiophene) (P3HT) and [6,6]-phenyl-C₆ᵢ-butyric acid methyl ester (PCBM) are in a ratio 1:0.8-1:4; spin coating the mixed solution on the electronic buffer layer in an inert atmosphere; standing for 24 hours-48 hours at room temperature to obtain the active layer.

Preferably, a weight of poly(3-hexylthiophene) (P3HT) and [6,6]-phenyl-C₆₁-butyric acid methyl ester (PCBM) are in a ratio 1:0.8.

Preferably, preparation of the active layer further comprises a step of annealing at a temperature of 50° C.-200° C. for 5 minutes-100 minutes.

Preferably, a concentration of the mixed solution of poly(3-hexylthiophene) (P3HT) and [6,6]-phenyl-C₆₁-butyric acid methyl ester (PCBM) is in a range of 8 mg/ml-24 mg/ml. More preferably, the concentration of the mixed solution of poly(3-hexylthiophene) and [6,6]-phenyl-C₆₁-butyric acid methyl ester is 18 mg/ml.

Preferably, after spin-coating the mixed solution, a step of annealing at a temperature of 200° C. for 5 minutes is performed.

Preferably, the step of spin-coating is conducted at a speed of 4000 rpm-6000 rpm for 10 s-30 s.

Total reflection of the sunlight is realized by controlling ratio and concentration of P3HT and PCBM in active layer, achieving a refractive index of about 1.7.

Preferably, the solvent is methylbenzene, dimethylbenzene, chlorobenzene or chloroform.

Preferably, a thickness of the active layer is in a range of 80 nm-300 nm. More preferably, the thickness of the active layer is 200 nm.

In a second aspect, the present invention provides a polymer solar cell comprising a glass substrate, a cathode, an electronic buffer layer, an active layer and an anode stacked successively; the anode includes poly(3,4-ethylenedioxythiophene) and polystyrene sulfonate mixed with zinc oxide; a weight of zinc oxide and poly(3,4-ethylenedioxythiophene) are in a ratio 0.75:1-6:1, and a weight of poly(3,4-ethylenedioxythiophene) and polystyrene sulfonate are in a ratio 2:1-6:1.

Preferably, a particle size of the zinc oxide is in a range of 50 nm-200 nm.

Preferably, a thickness of the anode is in a range of 100 nm-300 nm.

In the cathode, zinc oxide is dissolved to ionize zinc. After the step of drying, ionic compound of zinc is formed and acts as a conductor of electricity. PEDOT is able to transport holes, which makes the anode to be able to act as a hole transport layer and anode per se.

Preferably, a thickness of the anode is in a range of 100 nm-300 nm.

Preferably, the glass substrate is common and commercially available glass.

Preferably, a material of the cathode is aluminium (Al), silver (Ag), gold (Au) or platinum (Pt). More preferably, the material of the cathode is aluminium (Al).

Preferably, a thickness of the cathode is in a range of 10 nm-30 nm. More preferably, the thickness of the cathode is 15 nm.

Preferably, a material of the electronic buffer layer is lithium fluoride (LiF), lithium carbonate (Li₂CO₃) or cesium carbonate (Cs₂CO₃). More preferably, the material of the electronic buffer layer is cesium carbonate (Cs₂CO₃).

More preferably, a thickness of the electronic buffer layer is in a range of 0.5 nm-10 nm. More preferably, the thickness of the electronic buffer layer is 2 nm.

Preferably, material of the active layer comprises poly(3-hexylthiophene) (P3HT) and [6,6]-phenyl-C₆₁-butyric acid methyl ester (PCBM). [6,6]-phenyl-C61-butyric acid methyl ester which is derived from C₆₀ has a molecular formula of C₇₂H₁₄O₂. A weight of P3HT and PCBM are in a ratio 1:0.8-1:4.

Preferably, the weight of P3HT and PCBM are in the ratio 1:0.8.

Preferably, a thickness of the active layer is in a range of 80 nm-300 nm. More preferably, the thickness of the active layer is 200 nm.

One important factor affecting power conversion efficiency of solar cell is utilization of sunlight. Currently, a common method for increasing the absorption of sunlight is to modify the structure of the material of active layer. The present invention improves absorption of sunlight by preparing anode using mixed materials, thus increasing power conversion efficiency of polymer solar cell. The anode of the polymer solar cell of the present invention is prepared by mixing poly(3,4-ethylenedioxythiophene) (PEDOT) and polystyrene sulfonate (PSS) with zinc oxide (ZnO). PEDOT has a refractive index of about 1.5, whereas active layer of the present invention has a refractive index of about 1.7. Difference between anode and active layer in refractive index causes the sunlight passing through the active layer to be scattered and totally reflected, and then absorbed. The anode further contains zinc acetate particles, which have a large particle size and is able to scatter the light, thus improving utilization of the sunlight and increasing power conversion efficiency of polymer solar cell.

The present inventions providing polymer solar cell and preparation method thereof comprise the following benefits.

(1) In the polymer solar cell of the present invention, the light is totally reflected back to active layer and absorbed due to the difference of anode and active layer in refractive index. The anode further contains zinc acetate particles, which have a large particle size and is able to scatter the light, thus improving utilization of the light and increasing power conversion efficiency of polymer solar cell.

(2) ITO glass is usually used as an anode of polymer solar cell. However, indium element may permeate the glass, leading to a reduction of lifetime of polymer solar cell. Further, indium is a high cost rare element of a somewhat toxicity. Anode of the present invention is prepared by mixing poly(3,4-ethylenedioxythiophene) and polystyrene sulfonate with zinc oxide. The present invention has an advantage of low cost and good stability.

(3) Anode of the polymer solar cell of the present invention has a high electrical conductivity (from PEDOT and Zn ions) and high injection efficiency (from PEDOT). The anode is able to act as a hole buffer layer and anode per se. Preparation of solar cell is greatly simplified by not preparing hole buffer layer and anode separately.

(4) Some oxidizable metals, such as Al and Ag, are usually used as material of cathode. The polymer solar cell of the present invention uses a reversed structure where an electronic buffer layer, an active layer and an anode are successively prepared on a cathode. This could prevent the cathode from being oxidized and facilitate improving the lifetime of a polymer solar cell and enable the product and method to have industrialized application prospects.

### BRIEF DESCRIPTION OF THE DRAWINGS

FIG. 1 shows structure of the polymer solar cell comprising a glass substrate 1, a cathode 2, an electronic buffer layer 3, an active layer 4 and an anode 5.

FIG. 2 shows current density-voltage curves of the polymer solar cell prepared according to Example 1 and a commonly encountered polymer solar cell, corresponding to curve 1 and curve 2, respectively.

### DETAILED DESCRIPTION OF ILLUSTRATED EMBODIMENTS

The invention will now be described in detail on the basis of preferred embodiments. It is to be understood that various changes may be made without departing from the spirit and scope of the inventions.

### Example 1

A method for preparing polymer solar cell comprises the following steps.

(1) After a photolithography process, glass was cut into the size of 2×2 cm and the luminous area was 0.3×0.3 cm. The glass was then sonicated successively with detergent, deionized water, acetone, ethanol and isopropanol for 15 minutes to remove the organic pollutant on the surface of the glass.

(2) A cathode of Al and an electronic buffer layer of Cs₂CO₃ were deposited successively on the glass by using a high vacuum deposition device (Shenyang Scientific Instrument Development Center Co., Ltd. China. Pressure<1×10⁻³ Pa). Cathode was deposited under a pressure of 5×10⁻⁴ Pa at a speed of 5 nm/s. Thickness of the cathode was 15 nm. Electronic buffer layer was deposited under a pressure of 5×10⁻⁴ Pa at a speed of 0.2 nm/s. Thickness of the electronic buffer layer was 2 nm.

(3) Preparation of active layer. To a stirred 0.5 ml of chlorobenzene were added 5 mg of P3HT and 4 mg of PCBM to obtain a mixed solution of P3HT and PCBM with a concentration of 18 mg/ml. In a glove box filled with inert gas, the mixed solution was spin-coated on the electronic buffer layer at a speed of 5000 rpm for 15 s. This was allowed to stand for 24 hours at room temperature, and then annealed at 200° C. for 5 minutes to obtain an active layer. Thickness of the active layer was 200 nm.

(4) Preparation of anode on the active layer. ZnO having a particles size of 100 nm was dissolved in acetic acid to obtain a ZnO solution having a concentration of 0.4 g/ml. To chlorobenzene was added PEDOT and PSS to obtain a solution of PEDOT and PSS. Molecular weight of PEDOT is in a range of 13000-50000. In the solution of PEDOT and PSS, a weight of PEDOT and PSS are in a ratio 5:1, and the solution comprises 4% by weight of PEDOT. A weight of ZnO and PEDOT are in a ratio 5:1. According to a volume ratio of 1:2, the ZnO solution is mixed with the solution of PEDOT and PSS to obtain a second mixed solution.

The second mixed solution was spin coated on the active layer at a speed of 4000 rpm for 20 s. After that, this was dried in nitrogen gas atmosphere at 150° C. for 30 minutes to obtain an anode. Thickness of the anode was 250 nm. A polymer solar cell of the present invention was made.

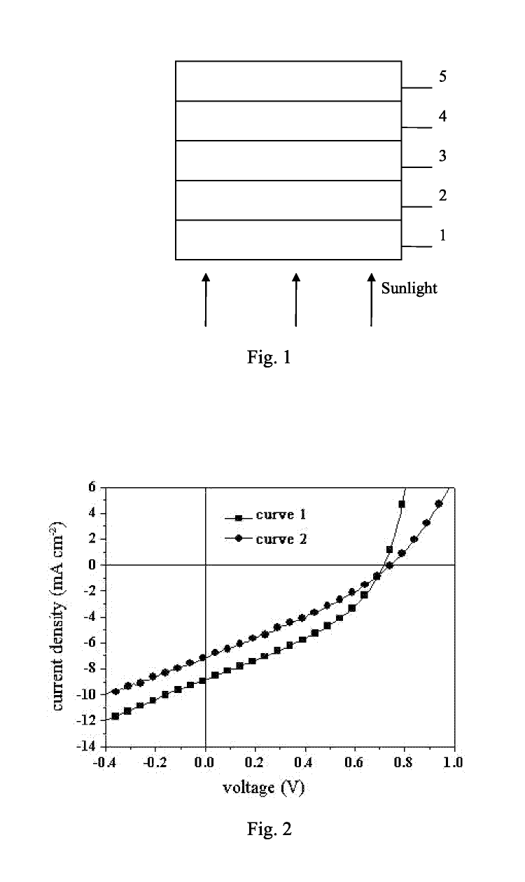

The polymer solar cell of the present invention comprises a glass substrate 1, a cathode 2, an electronic buffer layer 3, an active layer 4 and an anode 5. FIG. 1 shows the structure of the polymer solar cell of the present invention. The structure of the polymer solar cell of this embodiment can be described as: Glass substrate/Al/Cs₂CO₃/(P3HT:PCBM)/(ZnO:PEDOT:PSS). (ZnO:PEDOT:PSS) means that the anode is prepared by mixing PEDOT and PSS with ZnO. (P3HT:PCBM) means that material of the active layer includes P3HT and PCBM.

As a comparison, a commonly encountered polymer solar cell was prepared. Structure of the comparative cell can be described as ITO/(PEDOT:PSS)/(P3HT:PCBM)/Cs₂CO₃/Al. (PEDOT:PSS) means that material of the hole buffer layer includes PEDOT and PSS. (P3HT:PCBM) means the material of the active layer includes P3HT and PCBM. Anode used herein was ITO, i.e. indium tin oxide. Thickness of ITO layer was 120 nm. Material of the hole buffer layer was mixture of PEDOT and PSS. The hole buffer layer was prepared as follows. PEDOT and PSS in a ratio of 5:1 (by weight) were dissolved with water to produce an aqueous solution of PEDOT and PSS, where a mass percentage of PEDOT was 5%. The aqueous solution was then coated on the cathode by spin-coating at a speed of 5000 rpm for 15 s. After drying, a hole buffer layer was obtained. The thickness of the buffer layer was 80 nm. An active layer was prepared in a corresponding manner as described in Example 1. Thickness of the active layer was 200 nm. An electronic buffer layer was prepared in a corresponding manner as described in Example 1. Material of the electronic buffer layer was Cs₂CO₃, and thickness of the electronic buffer layer was 2 nm. A cathode was prepared in a corresponding manner as described in Example 1. Material of the cathode was Al, and thickness of the cathode was 80 nm. By comparison, the present invention uses a reversed structure. Anode of the present invention is prepared by mixing hole buffer material with ZnO. The anode is able to act as a hole buffer layer and anode per se, which greatly simplifies the preparation process.

### Example 2

A method for preparing polymer solar cell comprises the following steps.

(1) After a photolithography process, glass was cut into the size of 2×2 cm and the luminous area was 0.3×0.3 cm. The glass was then sonicated successively with detergent, deionized water, acetone, ethanol and isopropanol for 15 minutes to remove the organic pollutant on the surface of the glass.

(2) A cathode of Ag and an electronic buffer layer of LiF were deposited successively on the glass by using a high vacuum deposition device (Shenyang Scientific Instrument Development Center Co., Ltd. China. Pressure<1×10⁻³ Pa). Cathode was deposited under a pressure of 5×10⁻³ Pa at a speed of 10 nm/s. Thickness of the cathode was 10 nm. Electronic buffer layer was deposited under a pressure of 5×10⁻³ Pa at a speed of 1 nm/s. Thickness of the electronic buffer layer was 0.7 nm.

(3) Preparation of active layer. To a stirred 1 ml of chloroform were added 4.8 mg of P3HT and 19.2 mg of PCBM to obtain a mixed solution of P3HT and PCBM with a concentration of 24 mg/ml. In a glove box filled with inert gas, the mixed solution was spin-coated on the electronic buffer layer at a speed of 4000 rpm for 30 s. This was allowed to stand for 36 hours at room temperature to obtain an active layer. Thickness of the active layer was 80 nm.

(4) Preparation of anode on the active layer. ZnO having a particles size of 200 nm was dissolved in acetic acid to obtain a ZnO solution having a concentration of 0.6 g/ml. To chlorobenzene were added PEDOT and PSS to obtain a solution of PEDOT and PSS.

Molecular weight of PEDOT is in a range of 13000-50000. In the solution of PEDOT and PSS, a weight of PEDOT and PSS are in a ratio 2:1, and the solution comprises 1% by weight of PEDOT. A weight of ZnO and PEDOT are in a ratio 6:1. According to a volume ratio of 1:10, the ZnO solution is mixed with the solution of PEDOT and PSS to obtain a second mixed solution.

The second mixed solution was spin coated on the active layer at a speed of 2000 rpm for 60 s. After that, this was dried in nitrogen gas atmosphere at 50° C. for 30 minutes to obtain an anode. Thickness of the anode was 100 nm. A polymer solar cell of the present invention was made.

The polymer solar cell of the present invention comprises a glass substrate, a cathode, an electronic buffer layer, an active layer and an anode. The structure of the polymer solar cell of this embodiment can be described as: Glass substrate/Ag/LiF/(P3HT:PCBM)/(ZnO:PEDOT:PSS). (ZnO:PEDOT:PSS) means that the anode was prepared by mixing PEDOT and PSS with ZnO. (P3HT:PCBM) means that material of the active layer includes P3HT and PCBM.

### Example 3

A method for preparing polymer solar cell comprises the following steps.

(1) After a photolithography process, glass was cut into the size of 2×2 cm and the luminous area was 0.3×0.3 cm. The glass was then sonicated successively with detergent, deionized water, acetone, ethanol and isopropanol for 15 minutes to remove the organic pollutant on the surface of the glass.

(2) A cathode of Au and an electronic buffer layer of Cs₂CO₃ were deposited successively on the glass by using a high vacuum deposition device (Shenyang Scientific Instrument Development Center Co., Ltd. China. Pressure<1×10⁻³ Pa). Cathode was deposited under a pressure of 2×10⁻⁵ Pa at a speed of 1 nm/s. Thickness of the cathode was 30 nm. Electronic buffer layer was deposited under a pressure of 2×10⁻⁵ Pa at a speed of 0.1 nm/s. Thickness of the electronic buffer layer was 0.5 nm.

(3) Preparation of active layer. To a stirred 1 ml of chloroform were added 4 mg of P3HT and 12 mg of PCBM to obtain a mixed solution of P3HT and PCBM with a concentration of 16 mg/ml. In a glove box filled with inert gas, the mixed solution was spin-coated on the electronic buffer layer at a speed of 6000 rpm for 10 s. This was allowed to stand for 20 hours at room temperature, and then annealed at 100° C. for 100 minutes to obtain an active layer. Thickness of the active layer was 200 nm.

(4) Preparation of anode on the active layer. ZnO having a particles size of 50 nm was dissolved in acetic acid to obtain a ZnO solution having a concentration of 0.05 g/ml. To chlorobenzene were added PEDOT and PSS to obtain a solution of PEDOT and PSS.

Molecular weight of PEDOT is in a range of 13000-50000. In the solution of PEDOT and PSS, a weight of PEDOT and PSS are in a ratio 6:1, and the solution comprises 5% by weight of PEDOT. A weight of ZnO and PEDOT are in a ratio 0.75:1. According to a volume ratio of 3:4, the ZnO solution is mixed with the solution of PEDOT and PSS to obtain a second mixed solution.

The second mixed solution was spin coated on the active layer at a speed of 6000 rpm for 10 s. After that, this was dried in nitrogen gas atmosphere at 200° C. for 10 minutes to obtain an anode. Thickness of the anode was 300 nm. A polymer solar cell of the present invention was made.

The polymer solar cell of the present invention comprises a glass substrate, a cathode, an electronic buffer layer, an active layer and an anode. The structure of the polymer solar cell of this embodiment can be described as: Glass substrate/Au/Cs₂CO₃/(P3HT:PCBM)/(ZnO:PEDOT:PSS). (ZnO:PEDOT:PSS) means that the anode was prepared by mixing PEDOT and PSS with ZnO. (P3HT:PCBM) means that material of the active layer includes P3HT and PCBM.

### Example 4

A method for preparing polymer solar cell comprises the following steps.

(1) After a photolithography process, glass was cut into the size of 2×2 cm and the luminous area was 0.3×0.3 cm. The glass was then sonicated successively with detergent, deionized water, acetone, ethanol and isopropanol for 15 minutes to remove the organic pollutant on the surface of the glass.

(2) A cathode of Pt and an electronic buffer layer of Li₂CO₃ were deposited successively on the glass by using a high vacuum deposition device (Shenyang Scientific Instrument Development Center Co., Ltd. China. Pressure<1×10⁻³ Pa). Cathode was deposited under a pressure of 5×10⁻⁵ Pa at a speed of 8 nm/s. Thickness of the cathode was 12 nm. Electronic buffer layer was deposited under a pressure of 5×10⁻⁵ Pa at a speed of 0.5 nm/s. Thickness of the electronic buffer layer was 10 nm.

(3) Preparation of active layer. To a stirred 1 ml of chloroform were added 2.67 mg of P3HT and 5.33 mg of PCBM to obtain a mixed solution of P3HT and PCBM with a concentration of 8 mg/ml. In a glove box filled with inert gas, the mixed solution was spin-coated on the electronic buffer layer at a speed of 5000 rpm for 20 s. This was allowed to stand for 48 hours at room temperature, and then annealed at 70° C. for 100 minutes to obtain an active layer. Thickness of the active layer was 300 nm.

(4) Preparation of anode on the active layer. ZnO having a particles size of 80 nm was dissolved in acetic acid to obtain a ZnO solution having a concentration of 0.2 g/ml. To chlorobenzene were added PEDOT and PSS to obtain a solution of PEDOT and PSS.

Molecular weight of PEDOT is in a range of 13000-50000. In the solution of PEDOT and PSS, a weight of PEDOT and PSS are in a ratio 3:1, and the solution comprises 2% by weight of PEDOT. A weight of ZnO and PEDOT are in a ratio 4:1. According to a volume ratio of 2:5, the ZnO solution is mixed with the solution of PEDOT and PSS to obtain a second mixed solution.

The second mixed solution was spin coated on the active layer at a speed of 2500 rpm for 30 s. After that, this was dried in nitrogen gas atmosphere at 50° C. for 20 minutes to obtain an anode. Thickness of the anode was 180 nm. A polymer solar cell of the present invention was made.

The polymer solar cell of the present invention comprises a glass substrate, a cathode, an electronic buffer layer, an active layer and an anode. The structure of the polymer solar cell of this embodiment can be described as: Glass substrate/Pt/Li₂CO₃/(P3HT:PCBM)/(ZnO:PEDOT:PSS). (ZnO:PEDOT:PSS) means that the anode was prepared by mixing PEDOT and PSS with ZnO. (P3HT:PCBM) means that material of the active layer includes P3HT and PCBM.

### Comparative Example

A current-voltage tester (Keithley instruments Inc. US. model: 2602) and a white light source were used to detect current density of the polymer solar cell while varying the voltage. The white light was simulated sunlight produced by a xenon lamp (Osram, 500 W) and a light filter (AM1.5). FIG. 2 shows current density-voltage curves of the polymer solar cell prepared according to Example 1 and a commonly encountered polymer solar cell, corresponding to curve 1 and curve 2, respectively.

Current density of the polymer solar cell prepared according to Example 2-4 were detected while varying voltage. Some performance data, such as short-circuit current, open-circuit voltage, power conversion efficiency and fill factor, were obtained and shown in Table. 1. Table 1 shows performances of the polymer solar cell prepared according to Example 1-4 and the comparative cell. The symbol “η” herein is power conversion efficiency.

TABLE 1
performances of the polymer solar cell prepared according
to Example 1-4 and the comparative embodiment

| | short-circuit | open-circuit | | |
|---|---|---|---|---|
| Solar cell | current (mA/cm²) | voltage (V) | η(%) | fill factor |
| comparative | 6.18 | 0.74 | 1.40 | 0.31 |
| embodiment | | | | |
| Example 1 | 9.46 | 0.73 | 2.37 | 0.34 |
| Example 2 | 8.00 | 0.72 | 1.89 | 0.33 |
| Example 3 | 6.51 | 0.72 | 1.52 | 0.32 |
| Example 4 | 6.65 | 0.74 | 1.67 | 0.34 |

It can be seen from Table 1 that short-circuit current and power conversion efficiency of the comparative embodiment are 6.18 mA/cm² and 1.40%, respectively. However, short-circuit current of the polymer solar cell according to Examples 1-4 is increased to 6.51-9.46 mA/cm², and the power conversion efficiency is in a range of 1.52%-2.37%. It indicates that the present invention uses a reversed structure. Anode of the present invention is prepared by mixing PEDOT and PSS with ZnO. Anode of the polymer solar cell of the present invention has a high electrical conductivity and high injection efficiency. The light is totally reflected back to active layer and absorbed due to the difference of anode and active layer in refractive index, thus improving utilization of the sunlight and increasing power conversion efficiency of polymer solar cell. The product and method have industrialized application prospects.

While the present invention has been described with reference to particular embodiments, it will be understood that the embodiments are illustrative and that the invention scope is not so limited. Alternative embodiments of the present invention will become apparent to those having ordinary skill in the art to which the present invention pertains. Such alternate embodiments are considered to be encompassed within the spirit and scope of the present invention.

1. A method for preparing polymer solar cell, comprising:
providing a clean glass substrate and then preparing a cathode, an electronic buffer layer and an active layer successively on the glass substrate;
preparing an anode on the active layer by the following steps:
dissolving poly(3,4-ethylenedioxythiophene) and polystyrene sulfonate in chlorobenzene to obtain a solution of poly(3,4-ethylenedioxythiophene) and polystyrene sulfonate, where a weight of poly(3,4-ethylenedioxythiophene) and polystyrene sulfonate are in a ratio 2:1-6:1, and a percentage of poly(3,4-ethylenedioxythiophene) by weight of the solution of poly(3,4-ethylenedioxythiophene) and polystyrene sulfonate is in a range of 1%-5%,
dissolving zinc oxide in acetic acid to obtain a zinc oxide solution with a concentration of 0.05 g/ml-0.6 g/ml,
mixing the zinc oxide solution and the solution of poly(3,4-ethylenedioxythiophene) and polystyrene sulfonate in a volume ratio 1:10-3:4 to obtain a mixed solution, where a weight of zinc oxide and poly(3,4-ethylenedioxythiophene) are in a ratio 0.75:1-6:1;
spin-coating the mixed solution on the active layer, and then drying to obtain the anode;
obtaining a polymer solar cell.

2. The method for preparing polymer solar cell of claim 1, wherein a particle size of the zinc oxide is in a range of 50 nm-200 nm.

3. The method for preparing polymer solar cell of claim 1, wherein the step of spin-coating is conducted at a speed of 2000 rpm-6000 rpm for 10 s-60 s.

4. The method for preparing polymer solar cell of claim 1, wherein the step of drying is conducted in an inert atmosphere at a temperature of 50° C.-200° C. for 10 minutes-30 minutes.

5. The method for preparing polymer solar cell of claim 1, wherein the step of preparing an active layer comprises:
dissolving poly(3-hexylthiophene) and [6,6]-phenyl-C61-butyric acid methyl ester in a solvent to obtain a mixed solution of poly(3-hexylthiophene) and [6,6]-phenyl-C61-butyric acid methyl ester, where a weight of poly(3-hexylthiophene) and [6,6]-phenyl-C₆₁-butyric acid methyl ester are in a ratio 1:0.8-1:4;
spin-coating the mixed solution of poly(3-hexylthiophene) and [6,6]-phenyl-C61-butyric acid methyl ester on the electronic buffer layer in an inert atmosphere;
standing for 24 hours-48 hours at room temperature to obtain the active layer.

6. The method for preparing polymer solar cell of claim 5, wherein the step of preparing the active layer further comprises a step of annealing at a temperature of 50° C.-200° C. for 5 minutes-100 minutes.

7. The method for preparing polymer solar cell of claim 5, wherein a concentration of the mixed solution of poly(3-hexylthiophene) and [6,6]-phenyl-C₆₁-butyric acid methyl ester is in a range of 8 mg/ml-24 mg/ml.

8. The method for preparing polymer solar cell of claim 5, wherein the step of spin-coating is conducted at a speed of 4000 rpm-6000 rpm for 10 s-30 s.

9. A polymer solar cell comprising a glass substrate, a cathode, an electronic buffer layer, an active layer and an anode stacked successively; the anode includes poly(3,4-ethylenedioxythiophene) and polystyrene sulfonate mixed with zinc oxide; a weight of zinc oxide and poly(3,4-ethylenedioxythiophene) are in a ratio 0.75:1-6:1, and a weight of poly(3,4-ethylenedioxythiophene) and polystyrene sulfonate are in a ratio 2:1-6:1.

10. The polymer solar cell of claim 9, wherein a particle size of zinc oxide is in a range of 50 nm-200 nm, a thickness of the anode is in a range of 100 nm-300 nm.
